(19) United States
(12) Patent Application Publication
(10) Pub. No.: US 2026/0136140 A1
(43) Pub. Date: May 14, 2026

(54) Microelectromechanical Systems (MEMS) Transducers for High Sound Pressure Level (SPL) Measurements

(71) Applicant: Shure Acquisition Holdings, Inc., Niles, IL (US)

(72) Inventors: Roger Stephen Grinnip, III, Lake Zurich, IL (US); Kenneth James Platz, Park Ridge, IL (US)

(21) Appl. No.: 19/386,914

(22) Filed: Nov. 12, 2025

Related U.S. Application Data
(60) Provisional application No. 63/719,968, filed on Nov. 13, 2024.

(51) Int. Cl. H04R 19/04; B81B 3/00; H04R 7/04

(52) U.S. Cl. CPC H04R 19/04; B81B 3/0021; H04R 7/04; B81B 2201/0257; B81B 2203/0127; B81B 2207/012; H04R 2201/003

(57) ABSTRACT

Aspects of the disclosure relate to microelectromechanical systems (MEMS) devices for pressure measurements. In particular, various examples herein describe techniques for limiting a diaphragm displacement of capacitive MEMS transducers to enable high sound pressure level (SPL) measurements. A reduced diaphragm displacement may be achieved by using a cap over the diaphragm of the MEMS transducer to reduce a volume of a back cavity of a MEMS transducer. A smaller back cavity may acoustically load the diaphragm and reduce the diaphragm displacement. Additionally, or alternatively, a reduced diaphragm displacement may also be achieved by stacking multiple MEMS transducers over each other such that the multiple MEMS transducers are in series acoustically.

### CROSS-REFERENCE TO RELATED APPLICATION

This application claims the benefit of U.S. Provisional Patent Application No. 63/719,968, filed on Nov. 13, 2024, which is fully incorporated herein by reference.

### TECHNICAL FIELD

Aspects of the disclosure generally relate to microelectromechanical systems (MEMS) transducers, and more specifically relate to MEMS transducers for sound pressure measurements and/or microphone applications.

### BACKGROUND

Multiple microphone types, employing different technologies, are commercially available. Microphone types include, for example, dynamic microphones, condenser microphones, ribbon microphones, and microelectromechanical systems (MEMS) microphones. MEMS microphones offer many advantages over other microphone technologies. For example, MEMS microphones have a small footprint, a low cost, low power consumption, and allow easy integration with electronic components in a compact package.

A common MEMS transducer technology involves the use a diaphragm whose deformation and/or vibration may be electrically sensed. For example, a diaphragm of the MEMS transducer may be configured to deform/vibrate based on an input pressure or sound. Deformation or vibration of the diaphragm may be measured using different techniques. In one example, deformation or vibration of the diaphragm may be sensed as a change in capacitance of a capacitor comprising the diaphragm and a backplate in proximity to the diaphragm.

### SUMMARY

The following summary presents a simplified summary of certain features. The summary is not an extensive overview and is not intended to identify key or critical elements.

Various examples herein describe diaphragm-based MEMS transducer architectures for microphone/sound pressure measurement applications. The MEMS transducer architectures as described herein enable reduced diaphragm displacement (e.g., in comparison to conventional devices) to provide high dynamic range and/or an ability to perform high sound pressure level (SPL) measurements. An example MEMS transducer may comprise a backplate and a diaphragm spaced away from the backplate. The MEMS transducer may comprise a cap affixed over the diaphragm and enclosing a cavity over the diaphragm. An opening of the cavity may have substantially the same dimensions as a boundary of the diaphragm. The cavity may have a reduced volume and, consequently, a reduced acoustic compliance that may load and limit a vibration of the diaphragm.

An example MEMS device may comprise a plurality of stacked MEMS transducers. Each MEMS transducer, of the plurality of stacked MEMS transducers, may comprise a corresponding backplate and a corresponding diaphragm. For example, a MEMS transducer may be stacked over and attached to a lower MEMS transducer such that a backplate (or a diaphragm) of the MEMS transducer is near (e.g., above, adjacent to) a diaphragm (or a backplate) of the lower MEMS transducer. The stacked MEMS transducers may provide a higher acoustic impedance to incident sound pressure, thereby limiting diaphragm displacement in each of the MEMS transducers. These and other features and advantages are described in greater detail below.

### BRIEF DESCRIPTION OF THE DRAWINGS

The present disclosure is illustrated by way of example and not limited in the accompanying figures in which like reference numerals indicate similar elements and in which:

FIG. 1A shows a cross-section of an example MEMS device,

FIG. 1B shows a simplified lumped element model of a MEMS device,

FIG. 2 shows an example relationship between an input SPL and a THD for a capacitive MEMS microphone,

FIG. 3 shows a cross-section of an example MEMS device with reduced back cavity compliance,

FIG. 4A shows a cross-section of an example MEMS device with a stacked transducer architecture,

FIG. 4B shows an example architecture for electrically interconnecting MEMS transducers in a MEMS transducer stack,

FIG. 4C shows a simplified lumped element model of a MEMS transducer stack,

FIG. 5 shows an example circuit for biasing individual MEMS transducers in a MEMS transducer stack,

FIG. 6 shows an example transducer assembly comprising multiple MEMS devices, and

FIG. 7 shows an example method for assembling a MEMS transducer stack.

### DETAILED DESCRIPTION

In the following description of various illustrative embodiments, reference is made to the accompanying drawings, which form a part hereof, and in which is shown, by way of illustration, various embodiments in which aspects of the disclosure may be practiced. It is to be understood that other embodiments may be utilized, and structural and functional modifications may be made, without departing from the scope of the present disclosure. It is noted that various connections between elements are discussed in the following description. It is noted that these connections are general and, unless specified otherwise, may be direct or indirect, wired or wireless, and that the specification is not intended to be limiting in this respect.

A typical MEMS transducer architecture comprises a diaphragm which deforms in response to incident pressure. When applied for sound pressure measurements and/or microphone applications, the deformation may correspond to vibrations/oscillations of the diaphragm in response to an incident acoustic pressure wave. In a capacitive MEMS transducer, the vibrations/oscillations of the diaphragm may be measured as a change in capacitance of a capacitor comprising the diaphragm and a fixed backplate. Use of MEMS transducers for pressure wave sensing and/or microphone applications provide multiple advantages over conventional approaches. For example, MEMS transducers provide advantages such as reduced size and compatibility with conventional printed circuit board (PCB) manufacturing processes (e.g., such as reflow soldering) when compared to dynamic microphones, condenser microphones, or ribbon microphones. However, MEMS transducers may be at a disadvantage in relation to at least some audio performance parameters.

MEMS transducers for sound pressure measurements provide a signal output that corresponds to an input sound pressure level (SPL). SPL may correspond to change in pressure (e.g., a deviation from ambient/atmospheric pressure) caused by an acoustic wave. MEMS transducers typically suffer from reduced sound pressure level (SPL) handling capability. High SPLs may cause larger deformation of a diaphragm of a capacitive MEMS transducer. The non-linear nature of the deformation of the diaphragm may cause a signal output to have a high total harmonic distortion (THD) at high SPLs. An additional factor that may limit the maximum SPL performance is that the diaphragm may contact the backplate when exposed to high incident pressures.

Various examples herein describe improved MEMS devices targeting a high pressure/SPL handling capability. A MEMS device (e.g., for microphone and/or sound pressure measurements) may comprise a diaphragm which is housed inside a cavity formed by a cover/cap. The cavity may have a diameter which is equal (or substantially equal) to a diameter of the diaphragm. Additionally, or alternatively, the MEMS device may have a stacked transducer architecture. For example, the MEMS device may comprise a plurality of transducers with each transducer comprising a corresponding diaphragm and a corresponding backplate. A transducer, of the MEMS device, may be stacked over a lower transducer, of the MEMS device, such that a backplate of the transducer is proximate to (e.g., near, directly above, adjacent to) a diaphragm of the lower transducer. The use of a cap over the diaphragm of a transducer and/or stacking multiple transducers may effectively reduce volume velocity of an incident acoustic wave. A reduced volume velocity may result in reduced diaphragm deformation, which may lead to a higher SPL handling capability of a MEMS device.

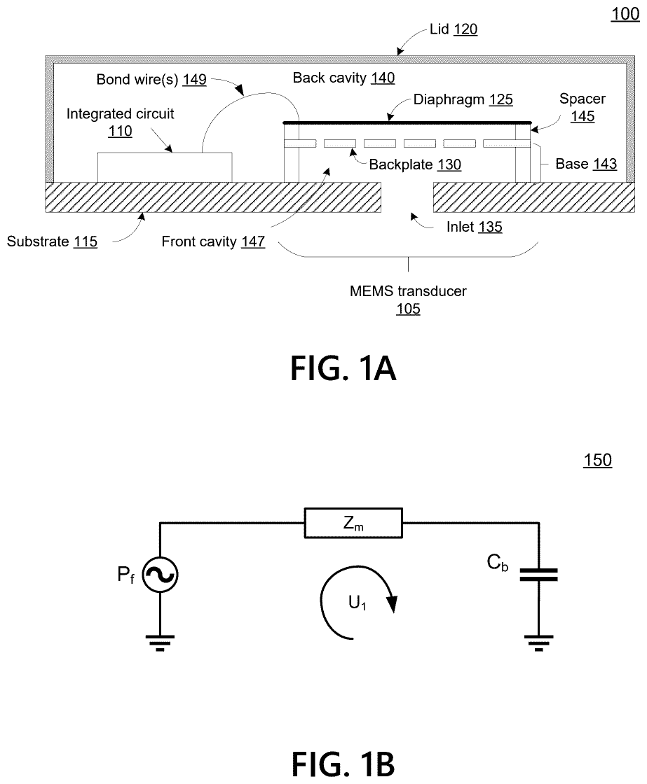

FIG. 1A shows a cross-section of an example MEMS device 100. The MEMS device 100 may correspond to a capacitive MEMS transducer for sound pressure measurements and/or microphone applications. The MEMS device 100 may comprise a MEMS transducer 105, an integrated circuit 110, a substrate 115, and a lid 120.

The MEMS transducer 105 may correspond to a capacitive MEMS transducer comprising a backplate 130 and a moveable (e.g., deformable) diaphragm 125. The backplate 130 may be fixed and/or rigid within the MEMS transducer 105. The backplate 130 and the diaphragm 125 may be positioned near to, and spaced apart from, each other. The backplate 130 and the diaphragm 125 may be conductive, and/or may include electrodes (e.g., in the form of conductive metallic layers), that enable the backplate 130 and the diaphragm 125 to together function as a capacitor. The backplate 130 may comprise perforations (e.g., vent holes) that allow the diaphragm 125 to be exposed to sound pressure and/or to mitigate damping of motion (e.g., vibration) of the diaphragm 125. In response to an incident sound pressure wave, the diaphragm 125 may oscillate/vibrate about an equilibrium position (e.g., in a direction orthogonal/perpendicular to a surface of the diaphragm 125.

The MEMS transducer 105 may additionally comprise a base 143 and a spacer 145. The backplate 130 and the diaphragm 125 may be mounted on the base 143 and may be separated from each other by the spacer 145. The spacer 145 may function as an electrically insulating layer between the backplate 130 and the diaphragm 125. In an example, the backplate 130 and the base 143 may correspond to a monolithic structure. The MEMS transducer 105 may be mounted on an inlet 135 located in the substrate 115. The inlet 135 may function as an acoustic port that transfers incident sound pressure to the MEMS transducer 105.

The MEMS transducer 105, as mounted on the substrate 115, may have a different arrangement of the diaphragm 125 and the backplate 130. While FIG. 1A shows the backplate 130 being near (e.g., directly above, adjacent to) the inlet 135, in other examples, the diaphragm 125 may be near (e.g., directly above, adjacent to) the inlet 135 (e.g., with the backplate 130 being located over the diaphragm 125 and away from the inlet 135). In other words, the diaphragm 125 of the MEMS transducer 105, as mounted on the substrate 115, may be below the backplate 130.

The integrated circuit 110 (e.g., an application-specific integrated circuit (ASIC)) may be mounted on the substrate 115 and may be electrically connected to the diaphragm 125 and the backplate 130 of the MEMS transducer 105. Electrical connection(s) between the integrated circuit 110 and the MEMS transducer 105 may be via one or more bond wire(s) 149. Additionally, or alternatively, the connection(s) between the integrated circuit 110 and the MEMS transducer 105 may be via conductive tracks on the substrate 115 (e.g., which may be a printed circuit board (PCB)). The integrated circuit 110 may be configured to measure a capacitance and/or a change in capacitance of the MEMS transducer 105 and generate an output signal corresponding to the capacitance and/or the change in capacitance. The output signal may correspond to pressure/SPL that the MEMS transducer 105 is exposed to via the inlet 135.

The MEMS transducer 105 and the integrated circuit 110 may be packaged on the substrate 115 using a lid 120. The lid 120 may define a cavity within which the MEMS transducer 105 and the integrated circuit 110 may be located. With respect to the MEMS device 100, the cavity may correspond to a back cavity 140 that is located on the side of the diaphragm 125 that is away from the inlet 135. A region between the inlet 135 and the backplate 130 may correspond to a front cavity 147 of the MEMS transducer 105.

The diaphragm 125, the backplate 130, and/or the base 143 may be fabricated from silicon (e.g., single crystal silicon, polysilicon, doped polysilicon, amorphous silicon), any other semiconductor material (e.g., GaAs, InP, Si/Ge, and/or SiC), a metal, and/or any other material. For example, the backplate 130 may be fabricated from single crystal silicon, and the diaphragm 125 may be fabricated from doped polysilicon. The spacer 145 may comprise any insulating material (e.g., silicon dioxide, silicon nitride, etc.). In an example, the MEMS transducer 105 may be fabricated using a semiconductor die (e.g., comprising silicon or any other semiconductor material) with one or more layers of material (e.g., polysilicon) that is deposited to form the diaphragm 125 and/or the backplate 130.

The lid 120 may be fabricated using metal, ceramic, polymer, and/or any other material. The substrate 115 may correspond to a PCB, and/or may comprise plastic, ceramic, and/or laminate material. In an example, the substrate 115 may comprise conductive lines, pins, and/or tabs that may be used to electrically connect (e.g., solder, surface mount, or connect using bond wires) the MEMS device 100 to one or more other components of a microphone system (not shown).

While the MEMS device 100 shows the inlet 135 through the substrate 115, in other examples, an inlet may instead be located on the lid 120. In some examples, inlets may be located on both the substrate 115 and the lid 120 (e.g., with one inlet on the substrate 115 and another inlet on the lid 120).

The MEMS transducer 105 and the integrated circuit 110, as shown in FIG. 1A, may correspond to separate structures. For example, the MEMS transducer 105 and the integrated circuit 110 may be fabricated on separate dies and mounted on the substrate 115. In other examples, the MEMS transducer 105 and the integrated circuit 110 may be fabricated on a same die.

Operation in a linear range of a MEMS transducer (e.g., the MEMS transducer 105) comprising a diaphragm may be simplified as a relation between a pressure difference ΔP across the diaphragm, a volume velocity U₁, and an acoustic impedance Zₘ of the MEMS transducer. For example, the pressure difference ΔP may be given as:

$$Δ P = {U}_{1} {Z}_{m} \qquad Equation ( l )$$

The above relation enables construction of a lumped element model of the MEMS transducer that may be used to analyze the effect of various elements of the MEMS transducer on the volume velocity. The volume velocity may determine a displacement of the diaphragm of the MEMS transducer. For example, the displacement of the diaphragm may be gives as:

$$η = \frac{{U}_{1}}{j ω {S}_{d}} \qquad Equation ( 2 )$$

where ω=2πf (with f being the frequency) and S_{d} may be an effective surface area of the diaphragm.

FIG. 1B shows a simplified lumped element model 150 of a MEMS device (e.g., the MEMS device 100). The simplified lumped element model 150 may be used determine to a response of the MEMS device (e.g., a volume velocity within the MEMS device) to an incident pressure wave (e.g., acoustic wave). The volume velocity may be used to analyze a diaphragm displacement in response to the incident pressure wave.

The lumped element model 150 may be represented by a circuit comprising a pressure wave source P_{f} (e.g., via the inlet 135), an acoustic impedance Zₘ of a MEMS transducer (e.g., the MEMS transducer 105), and the acoustic compliance C_{b} of a back cavity defined by the diaphragm of the MEMS transducer and a lid of the MEMS device (e.g., the back cavity 140). U₁ may be the volume velocity of air within the MEMS transducer. For simplicity, an electromechanical coupling between electrical components (e.g., the integrated circuit 110) and mechanical components (e.g., the MEMS transducer 105) is assumed to be negligible and has been ignored in the lumped element model 150.

The loop equation of the lumped element model 150 may be given as:

$${P}_{f} - {U}_{1} {Z}_{m} - \frac{{U}_{1}}{{j ω C}_{b}} = 0 \qquad Equation ( 3 )$$

The impedance Zₘ of a MEMS transducer may be given as:

$${Z}_{m} = {R}_{m} + j ω {L}_{m +} \frac{1}{j ω {C}_{m}} \qquad Equation ( 4 )$$

where Rₘ may correspond to acoustic resistance (e.g., an air film resistance), Lₘ may correspond to an acoustic mass, and Cₘ may correspond to acoustic compliance (e.g., an acoustic compliance associated with the diaphragm). Using Equations (3) and (4), the volume velocity U₁ may be written as:

$${U}_{1} = \frac{{j ω C}_{m} {C}_{b} {P}_{f}}{( {C}_{m} + {C}_{b} ) + {j ω R}_{m} {C}_{m} {C}_{b} - {ω}^{2} {L}_{m} {C}_{m} {C}_{b}} \qquad Equation ( 5 )$$

Based on Equations (2) and (5), the diaphragm displacement n may be given as:

$$η = \frac{{C}_{m} {C}_{b} {P}_{f}}{{S}_{d} [ ( {C}_{m} + {C}_{b} ) + j ω {R}_{m} {C}_{m} {C}_{b} - {ω}^{2} {L}_{m} {C}_{m} {C}_{b} ]} \qquad Equation ( 6 )$$

Ignoring acoustic resistance (e.g., Rₘ≈0) and assuming that the acoustic compliance of the diaphragm Cₘ is much lower than the acoustic compliance C_{b} of a back cavity, Equation (6) reduces to:

$$η = \frac{{C}_{m} {P}_{f}}{{S}_{d} ( 1 - {ω}^{2} {L}_{m} {C}_{m} )} \qquad Equation ( 7 )$$

A mechanical resonance frequency of the MEMS transducer, ωₒ, may be equal to:

$${ω}_{o} = \sqrt{\frac{1}{{L}_{m} {C}_{m}}} \qquad Equation ( 8 )$$

For incident wave frequencies that are much lower than the mechanical resonance frequency of the MEMS transducer (e.g., which is typically above 20 kHz), the diaphragm displacement n may be given as:

$$η {\vert}_{ω << {ω}_{o}} = \frac{{C}_{m} {P}_{f}}{{S}_{d}} \qquad Equation ( 9 )$$

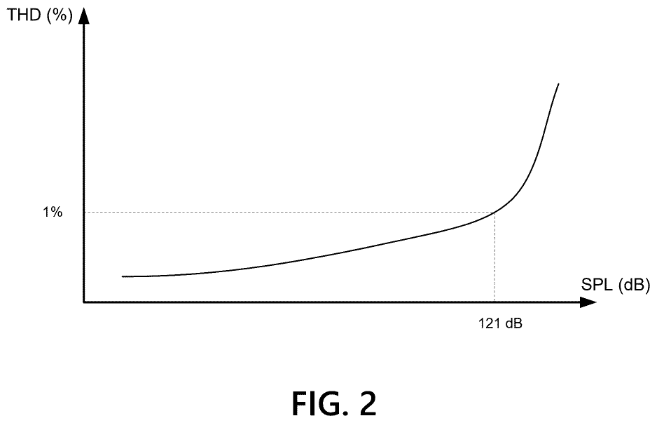

THD of microphones typically may be expressed as a function of incident pressure wave P_{f}. For example, FIG. 2 shows an example relationship between an input SPL and a THD for a capacitive MEMS transducer. A performance parameter that may be used to compare transducer performance is the SPL that results in defined THD (e.g., 1% THD). For example, with respect to the example MEMS transducer of FIG. 2, a 121 db SPL would result in 1% THD. A higher SPL for a given THD may be indicative of a better microphone performance (e.g., higher dynamic range).

As previously explained, a major cause of THD may be the non-linear deformation of the diaphragm, especially at the high SPLs. A MEMS transducer design that limits diaphragm displacement at higher SPLs may have favorable THD performance. Accordingly, diaphragm displacement may be used a constraint to design MEMS transducers with higher dynamic range (e.g., higher maximum SPL handling capability).

A maximum diaphragm displacement, that a MEMS transducer may be constrained to, may be determined using Equation (6) as:

$${η}_{max} = \frac{{C}_{m} {P}_{max}}{{S}_{d}} \qquad Equation ( 10 )$$

wherein Pₘₐₓ may be the pressure that results in the maximum diaphragm displacement.

Allowed the acoustic compliance of the back cavity C_{b} to “load” the mechanical system (e.g., movement of the diaphragm) may enable limiting of the diaphragm displacement. This may be achieved by reducing the acoustic compliance of the back cavity C_{b}. In such a scenario, the acoustic compliance of the diaphragm Cₘ may no longer be assumed to be much lower than the acoustic compliance C_{b} of a back cavity. The diaphragm displacement may be given by (e.g., using Equation (6) and for ω<<ωₒ):

$$η = \frac{{C}_{m} {C}_{b} {P}_{f}}{{S}_{d} ( {C}_{m} + {C}_{b} )} \qquad Equation ( 11 )$$

For η=ηₘₐₓ, and based on Equations (10) and (11), P_{f} may be related to Pₘₐₓ as:

$${P}_{f} = \frac{( {C}_{m} + {C}_{b} )}{{C}_{b}} {P}_{max} \qquad Equation ( 12 )$$

Equation (12) shows that if the back cavity compliance is allowed to load the diaphragm movement, a higher pressure P_{f} (e.g., P_{f}>Pₘₐₓ) would result in a same diaphragm displacement ηₘₐₓ as observed in a MEMS transducer where the back cavity compliance does not load the diaphragm. Based on Equation (12), we may also calculate C_{b}, for a given Cₘ and a desired P_{f}/Pₘₐₓ ratio. For example, for P_{f}=2Pₘₐₓ (e.g., to maintain a same THD/diaphragm displacement for a 6 dB SPL increase in incident pressure), we get C_{b}=Cₘ.

The acoustic compliance of the back cavity C_{b} may be reduced by reducing a size (e.g., a volume) of the back cavity. For example, a cap may be affixed over the diaphragm wherein a cavity defined by the cap is much smaller than the back cavity 140 of FIG. 1A.

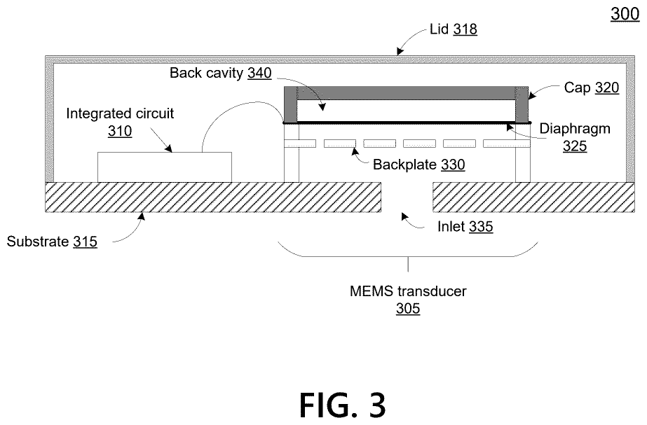

FIG. 3 shows a cross-section of an example MEMS device 300 with reduced back cavity compliance. The MEMS device 300 may correspond to a capacitive MEMS transducer for sound pressure measurements and/or microphone applications. The MEMS device 300 may be similar to MEMS device 100. For example, the MEMS device 300 may comprise a MEMS transducer 305, a corresponding integrated circuit 310, a substrate 315, and a lid 318, which may be substantially similar to the MEMS transducer 105, the integrated circuit 110, the substrate 115, and the lid 120, respectively. The MEMS transducer 305 may comprise a diaphragm 325 and a backplate 330 (e.g., substantially similar to the diaphragm 125 and the backplate 130, respectively) and may be mounted on an inlet 335.

The MEMS transducer 305 may comprise a cap 320 which may enclose a back cavity 340 over the diaphragm 325 (e.g., on a side of the diaphragm 325 that is located away from the inlet 335). As shown in FIG. 3, the cap 320 may be affixed over the diaphragm 325. As is clear based on a comparison of the MEMS device 100 and the MEMS device 300, the use of the cap 320 results in the back cavity 340 of the MEMS device 300 being substantially smaller than the back cavity 140 of the MEMS device 100. The smaller volume of the back cavity 340 may result in a reduced compliance of the back cavity 340. The reduced compliance of the back cavity 340 may effectively load the movement of the diaphragm 325. The compliance of the back cavity 340 may related to the volume of the cavity V_{b} as:

$${C}_{b} = \frac{{V}_{b}}{{ρ}_{0} {c}_{0}^{2}} \qquad Equation ( 13 )$$

where ρ₀c₀² is the adiabatic bulk modulus of air, with ρ₀ being air density and c₀ being the speed of sound in air.

In an example, an opening of the cavity enclosed by the cap 320 (e.g., a mouth of the cavity) may have the same, or substantially the same, shape and dimensions as the diaphragm 325 (e.g., an edge of the diaphragm 325). For example, if the diaphragm 325 is circular with diameter D, the mouth of the cavity may be circular and may have a diameter that is equal to D. If the diaphragm 325 is square with a side length L, the mouth of the cavity may be square with a side length that is equal to L. In other examples, the cavity may have different dimensions than the diaphragm as long as the volume of the cavity is constrained to be small enough to load the movement of the diaphragm 325.

The cap 320 may be fabricated on/using a same die that is used for fabricating other components of the MEMS transducer 305 (e.g., the diaphragm 325, the backplate 330, etc.). For example, the cap 320 may be formed as an integral part of a micromachining procedure used for the MEMS transducer 305. In other examples, the cap 320 may fabricated as a separate component (e.g., using a separate die or any other material) and attached to the other components of the MEEMS transducer 305 in a post-fabrication step. The cap may be fabricated from silicon (e.g., single crystal silicon, polysilicon, etc.), laminate (e.g., PCB material such as FR-4 composite or BT epoxy, or any other composite, etc.), polymer, metal, ceramic, and/or any other material.

The MEMS transducer 305, as mounted on the substrate 315, may have a different arrangement of the diaphragm 325 and the backplate 330. While FIG. 3 shows the backplate 330 being near (e.g., proximate to, adjacent to, above) the inlet 335, in other examples, the diaphragm 325 may be near (e.g., proximate to, adjacent to, above) the inlet 335 (e.g., with the backplate 330 being located over the diaphragm 325 and away from the inlet 335). In other words, the diaphragm 325 of the MEMS transducer 305, as mounted on the substrate 315, may be below the backplate 330. In such an example device, the cap 320 may be affixed over the backplate 330.

As described above, for an example scenario in which a same displacement needs to be obtained for a 6 dB increase in SPL (e.g., in comparison to MEMS transducer 105 that does not include a cap), C_{b} should equal Cₘ. For an example MEMS transducer with Cₘ=2×10⁻¹⁵ m⁵/N, using Equation (13), we may determine a volume of the cavity V_{b} as:

$${V}_{b} = {ρ}_{0} {c}_{0}^{2} {C}_{b} = 2.86 \times 1 {0}^{- 10} {m}^{3}$$

Assuming that the diaphragm 325 is circular and the cavity enclosed by the cap 320 has substantially the same diameter as the diaphragm 325, a cavity depth δ may be determined as:

$$δ = {V}_{b} / {S}_{d} \qquad Equation ( 14 )$$

where S_{d} is the effective diaphragm surface area. If the MEMS transducer has a diaphragm with a diameter D=0.6 mm (e.g., surface area S_{d}=2.83×10⁻⁷ m²), using Equation (14), cavity depth δ may be determined to be equal to approximately 1 mm.

Based on the lumped element model 150 of FIG. 1B, and Equations (3) and (4) that relate volume velocity U₁ to acoustic impedance Zₘ of a MEMS transducer, it is apparent that if the acoustic impedance Zₘ is increased, the volume velocity U₁ would be reduced. A reduced volume velocity U₁ would reduce a diaphragm displacement η of a MEMS transducer, thereby reducing a THD. One approach to increase the acoustic impedance would be to assemble a plurality of MEMS transducers in a manner that the MEMS transducers may be considered to be acoustically in series.

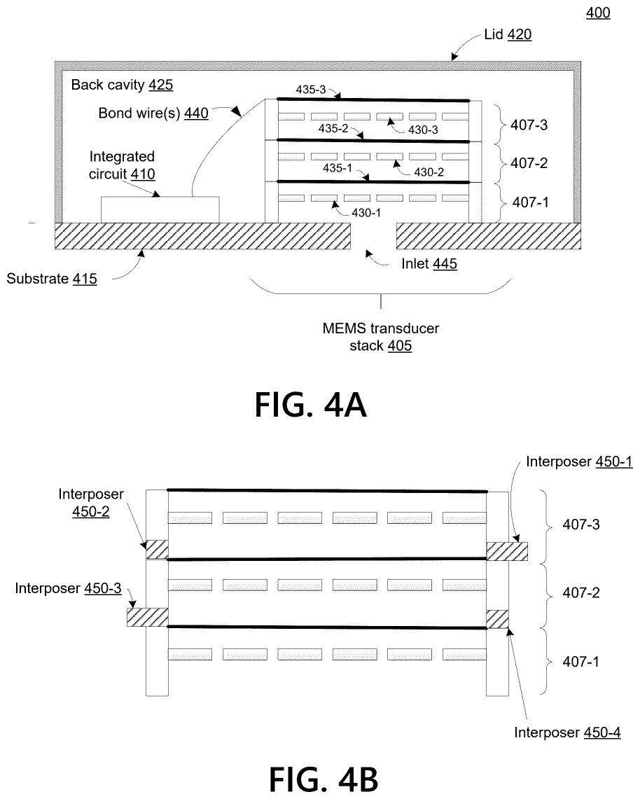

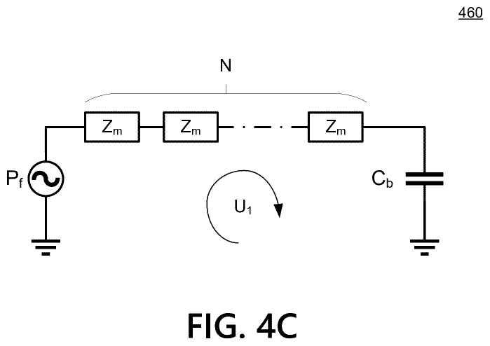

FIG. 4A shows a cross-section of an example MEMS device 400 with a stacked transducer architecture. The MEMS device 400 may correspond to a capacitive MEMS transducer for sound pressure measurements and/or microphone applications. The MEMS device 400 may comprise a MEMS transducer stack 405, an integrated circuit 410, a substrate 415, and a lid 420.

The MEMS transducer stack 405 may comprise a plurality of MEMS transducers 407. Each of the MEMS transducers 407 (e.g., MEMS transducers 407-1, 407-2, and 407-3) in the MEMS transducer stack 405 may be similar to the MEMS transducer 105 as described with respect to FIG. 1A. Each MEMS transducer 407 may comprise a corresponding backplate 430 and a corresponding diaphragm 435. For example, the MEMS transducer 407-1 may comprise a backplate 430-1 and a diaphragm 435-1. The MEMS transducer 407-2 may comprise a backplate 430-2 and a diaphragm 435-2. The MEMS transducer 407-3 may comprise a backplate 430-3 and a diaphragm 435-3. Each of the MEMS transducers 407 may additionally comprise a corresponding base and a corresponding spacer as described with respect to FIG. 1A. While the MEMS transducer stack 405 in FIG. 4A comprises three MEMS transducers 407, in other examples, the MEMS transducer stack 405 may comprise a different quantity of MEMS transducers (e.g., 2, 4, 5, 6, or any other quantity).

The MEMS transducers 407 may be identical in structure, dimensions, acoustic properties, and electrical performance. For example, the dimensions of the backplates 430 and the diaphragms 435 may be substantially identical across all the MEMS transducers 407, and each of the MEMS transducers 407 may provide same or substantially similar mechanical response and electrical output for a given pressure input. In other examples, however, the MEMS transducers 407 may be different from one another.

The MEMS transducer stack 405 may be assembled by vertically stacking multiple MEMS transducers 407 such that the MEMS transducer stack 405 comprises alternating backplates 430 and diaphragms 435. The backplates 430 and the diaphragms 435 may be parallel to one another. The stacking may be in a manner such that diaphragm of a first MEMS transducer that is lower in the stack is near (e.g., below, adjacent to, proximate to, directly under) a backplate of a second MEMS transducer stacked over the first MEMS transducer. For example, in the MEMS transducer stack 405, the MEMS transducer 407-2 may be stacked over the MEMS transducer 407-1 such that the diaphragm 435-1 of the MEMS transducer 407-1 is near the backplate 430-2 of the MEMS transducer 407-2. Similarly, the MEMS transducer 407-3 may be stacked over the MEMS transducer 407-2 such that the diaphragm 435-2 of the MEMS transducer 407-2 is near the backplate 430-3 of the MEMS transducer 407-3. The MEMS transducer stack 405 results in the individual MEMS transducers 407 being acoustically in series. Accordingly, each of the MEMS transducer share a same volume velocity.

MEMS transducers may have a different arrangement of a backplate and a diaphragm than shown in FIG. 4A but may be stacked in a similar manner. For example, a MEMS transducer may comprise a diaphragm that is below the backplate. Stacking of such MEMS transducers may be in a manner such that backplate of a first MEMS transducer that is lower in the stack is near (e.g., proximate to, adjacent to, directly under) a diaphragm of a second MEMS transducer that is stacked over the first MEMS transducer.

Each of the backplates 430 and the diaphragms 435 may be conductive, and/or may include electrodes (e.g., in the form of conductive metallic layers). A backplate 430 and a corresponding diaphragm 435 may together function as a capacitor. One or more of the backplates 430 may comprise perforations (e.g., vent holes) that allow the diaphragm to be exposed to sound pressure and/or to mitigate damping of motion (e.g., vibration) of the diaphragms 430. The MEMS transducer stack 405 may be mounted on an inlet 445 located in the substrate 415. The inlet 445 may function as an acoustic port that transfers incident sound pressure to the MEMS transducer stack 405.

The integrated circuit 410 (e.g., an ASIC) may be mounted on the substrate 415 and may be electrically connected to the MEMS transducer stack 405. Electrical connection(s) between the integrated circuit 410 and the MEMS transducer stack 405 may be via one or more bond wire(s) 440. Additionally, or alternatively, the connection(s) between the integrated circuit 410 and the MEMS transducer stack 405 may be via conductive tracks on the substrate 415 (e.g., which may be a PCB). The integrated circuit 410 may be configured to measure one or more capacitances or change in capacitances of the MEMS transducers 407 and generate an output signal corresponding to the one or more capacitances or change in capacitances. The output signal may correspond to pressure/SPL that the MEMS transducer stack 405 is exposed to via the inlet 445.

The MEMS transducer stack 405 and the integrated circuit 410 may be packaged on the substrate 415 using a lid 420. The lid 420 may define a cavity within which the MEMS transducer stack 405 and the integrated circuit 410 may be located. With respect to the MEMS device 400, the cavity may correspond to a back cavity 425 that is located on the side of the diaphragm 435-3 that is away from the inlet 445. A region between the inlet 445 and the backplate 430-1 may correspond to a front cavity of the MEMS transducer stack 405.

Each of the MEMS transducers 407, the lid 420, and/or the substrate 415 may be fabricated using materials as described with respect to the MEMS transducer 105. For example, the diaphragm 435 and the backplate 430 of each of the MEMS transducers 407 may be fabricated from silicon (e.g., single crystal silicon, polysilicon, doped polysilicon, amorphous silicon), any other semiconductor material (e.g., GaAs, InP, Si/Ge, and/or SiC), a metal, and/or any other material.

The MEMS transducers 407 may be fabricated on separate dies and stacked on top of each other. A batch fabrication technique may be applied in which wafers (e.g., each comprising multiple dies of MEMS transducers 407 in an array) may be stacked over each other and bonded using wafer bonding techniques (e.g., adhesive wafer bonding, anodic wafer bonding, direct bonding, eutectic bonding, etc.). The stacked and bonded wafers may be diced to obtain individual MEMS transducer stacks 405.

The lid 420 may be fabricated using metal, ceramic, polymer, and/or any other material. The substrate 415 may correspond to a PCB, and/or may comprise plastic, ceramic, and/or laminate material. In an example, the substrate 415 may comprise conductive lines, pins, and/or tabs that may be used to electrically connect (e.g., solder, surface mount, or connect using bond wires) the MEMS device 400 to one or more other components of a microphone or sound pressure measurement system (not shown).

While the MEMS device 400 shows the inlet 445 through the substrate 415, in other examples, an inlet may instead be located on the lid 420. In some examples, inlets may be located on both the substrate 415 and the lid 420 (e.g., with one inlet on the substrate 415 and another inlet on the lid 420).

FIG. 4B shows an example architecture for electrically interconnecting the MEMS transducers 407 in the MEMS transducer stack 405. As described previously, the MEMS transducers 407 may each be fabricated on separate dies and assembled to form the MEMS transducer stack 405. A MEMS transducer 407 may comprise contact pads that may be electrically connected to the diaphragm 430 and the backplate 435. To electrically connect contact pads from the different MEMS transducers 407 (e.g., MEMS transducers 407-1, 407-2, and 407-3), each associated with a corresponding die, to each other and to a circuit (e.g., the integrated circuit 410), interposers 450 may be configured in between the different MEMS transducers 407. The interposers 450 (e.g., interposers 450-1, 450-2, 450-3, and 450-4 as shown in FIG. 4B) may be used to route connections between contact pads located on separate MEMS transducers 407.

The interposers 450 may be fabricated using standard PCB manufacturing processes and may comprise plastic, ceramic, laminate (e.g., FR-4 composite, BT epoxy, etc.), etc. Additionally or alternatively, the interposers 450 may be fabricated using a semiconductor fabrication process (e.g., using an interposer die). Electrical routing (e.g., connections between the different contact pads on different MEMS transducers 407/dies) may be through the interposer (e.g., via internal trace layers), or may be external (e.g., using wire bonding).

FIG. 4C shows a simplified lumped element model 460 of a MEMS transducer stack. The lumped element model 460 may correspond to the MEMS transducer stack 405 as described with respect to FIGS. 4A and 4B. The lumped element model 460 may be represented by a circuit comprising a pressure wave source P_{f}, N MEMS transducers, each with acoustic impedance Zₘ (e.g., as given by Equation (4)), that are connected in series acoustically, and the acoustic compliance C_{b} of a back cavity (e.g., as defined by a lid of a package comprising the MEMS transducer stack 405, such as the lid 420). The lumped element model may ignore the small cavities (e.g., parallel compliances) formed between different MEMS transducers in the stack. These compliances may be negligible in comparison to Zₘ.

The loop equation of the lumped element model may be given as:

$${P}_{f} - {U}_{1} {NZ}_{m} - \frac{{U}_{1}}{j ω {C}_{b}} = 0 \qquad Equation ( 15 )$$

The combined acoustic impedance Zₜ of N acoustic impedances (each with impedance

$${Z}_{m} = {R}_{m} + j ω {L}_{m +} \frac{1}{j ω {C}_{m}} )$$

and the acoustic compliance C_{b} of the back cavity may be given as (e.g., assuming that C_{b}>>Cₘ and Rₘ≈0):

$${Z}_{t} = N \frac{( 1 - {ω}^{2} {L}_{m} {C}_{m} )}{j ω {C}_{m}} \qquad Equation ( 16 )$$

Using Equation (2), the diaphragm displacement of a MEMS transducer in the MEMS transducer stack may be given as:

$$η = \frac{{U}_{1}}{j ω {S}_{d}} = \frac{{P}_{f}}{j ω {S}_{d} {Z}_{t}} = \frac{{C}_{m} {P}_{f}}{{S}_{d} N ( 1 - {ω}^{2} {L}_{m} {C}_{m} )} \qquad Equation ( 17 )$$

Equation (16) implies that the MEMS transducer stack has a same mechanical resonance frequency

$$( e . g . , {ω}_{o} = \sqrt{\frac{1}{{L}_{m} {C}_{m}}} )$$

as that of a single MEMS transducer (e.g., as shown by Equation (8)). For ω<<ωₒ, diaphragm displacement n may be given as:

$$η {\vert}_{ω << {ω}_{o}} = \frac{{C}_{m} {P}_{f}}{{NS}_{d}} \qquad Equation ( 18 )$$

Based on comparison of Equations (9) and (18), it is apparent that stacking the MEMS transducers such that the MEMS transducers are in series acoustically results in reduced diaphragm displacement as compared to a single MEMS transducer. In particular, the use of N MEMS transducer stacks reduces a diaphragm displacement of each of the MEMS transducers by a factor of N. For example, if the diaphragm displacement needs to be halved (e.g., for a 6 dB increase in maximum SPL handling) as compared to a device comprising a single MEMS transducer (e.g., as shown in FIG. 1A), the number of MEMS transducers required is two (e.g., N=2).

While the lumped element model 460 assumed that the MEMS transducers 407 in the MEMS transducer stack 405 are identical, in other example devices, one or more of the MEMS transducers 407 may be different from others. For examples, one or more of the MEMS transducers 407 in the MEMS transducer stack 405 may have acoustic impedances that are different from one or more other MEMS transducers 407.

A signal output from a MEMS transducer (e.g., comprising a backplate and a diaphragm may be determined by measuring a change in capacitance (e.g., of a capacitor comprising the backplate and the diaphragm). For example, a direct current (DC) bias voltage may be applied to the capacitor. Diaphragm displacement due to incident pressure wave may be reflected as an alternating current (AC) signal across the capacitor. The sensitivity of the MEMS transducer (e.g., an AC signal output for a given diaphragm displacement) may be proportional to the bias voltage.

Reduced diaphragm displacement in the MEMS transducer stack (e.g., as shown by Equation (18)) may result in reduced sensitivity for each of the MEMS transducers. In order to increase an overall sensitivity of the MEMS transducer stack, the individual MEMS transducers in the stack may be wired electrically in series. Wiring the MEMS transducers in series allows summing of the output signal from each of the MEMS transducers in the stack. Therefore, even if a diaphragm displacement of an individual MEMS transducer reduces by a factor of N, the summing of output signals across the MEMS transducers that are wired in series enables the overall sensitivity of the MEMS transducer stack to be maintained.

Summing the output signals across the MEMS transducers may be under the assumption that signal output from each of the MEMS transducers is identical in phase. Since signal output is dependent on the applied bias voltage, this requires each of the MEMS transducers to have identical bias voltages. Wiring the MEMS transducers in series enables provision of a same bias voltage for each of the MEMS transducers.

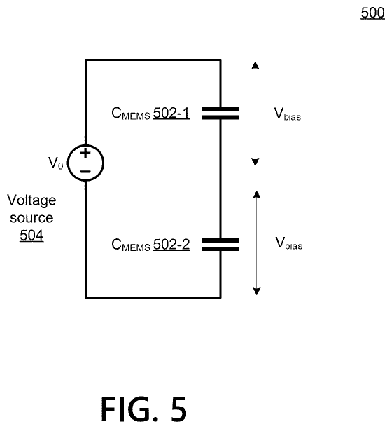

FIG. 5 shows an example circuit 500 for biasing individual MEMS transducers in a MEMS transducer stack. The circuit 500 shows an example in which two MEMS transducers 502 are biased by a voltage source 504. Each of MEMS transducers 502 may be identical and may have a nominal capacitance C_{MEMS}. The MEMS transducers 502 may be wired in series (e.g., as described above). While the circuit 500 shows two MEMS transducers 502, in other examples, a MEMS transducer stack may comprise a different number of MEMS transducers. The loop equation of the circuit 500 may yield:

$${V}_{0} - {E}_{0} {δ}_{0} - {E}_{0} {δ}_{0} = {V}_{0} - 2 {E}_{0} {δ}_{0} = 0 \qquad Equation ( 19 )$$

where V₀ may be applied DC bias voltage to the series connected MEMS transducers 502, E₀ may be the electric field within each MEMS transducer 502 (e.g., in a space between a diaphragm and a backplate), and δ₀ may be the nominal distance between a diaphragm and a backplate of a MEMS transducer 502. A bias voltage V_{bias} across each MEMS transducer 502 may be given as:

$${V}_{bias} = {E}_{0} {δ}_{0} = \frac{{V}_{0}}{2} \qquad Equation ( 20 )$$

Accordingly, each MEMS transducer 502 may be subject to identical bias voltage conditions, thereby allowing signal outputs from each of the MEMS transducers 502 to be summed.

However, bias voltage division across the MEMS transducers in series (e.g., as shown in FIG. 5) may result in reduced bias voltage being applied to each of the MEMS transducers (e.g., in comparison to a device that comprises only a single MEMS transducer). Reduced bias voltage may result in each MEMS transducer having a reduced sensitivity (e.g., reduced signal output) in comparison to a device that comprises only a single MEMS transducer. To ensure that the applied bias voltage to each MEMS transducer is not reduced, the bias voltage may be increased by a factor of N (e.g., the number of MEMS transducers in the stack). This ensures that the overall sensitivity is not affected by the bias voltage division.

Connecting the MEMS transducers in series may result in a decreased source capacitance, which may result in an increased electrical noise. To achieve a compromise between electrical noise and signal output, some of the MEMS transducers may be electrically wired in series while other MEMS transducers may be wired in parallel. This may ensure a higher source capacitance and reduced electrical noise.

In another example embodiment, signal output may only be obtained from a single MEMS transducer in the stack of MEMS transducers. The bias voltage in such an embodiment would need to be applied only to the MEMS transducer from which the signal output is being read. Since the MEMS transducers need not be wired in series, the source capacitance is not reduced which may provide improved noise performance.

Stacking multiple MEMS transducers (e.g., as described with respect to FIGS. 4A-4C) may be equivalent to reducing a back cavity compliance (e.g., as described with respect to FIG. 3) without needing to fabricate and integrate an additional part (e.g., the cap 320). Such an approach may also result in a mechanical resonance of a MEMS transducer not being increased (e.g., which may be an issue with a MEMS transducer that comprises the cap 320).

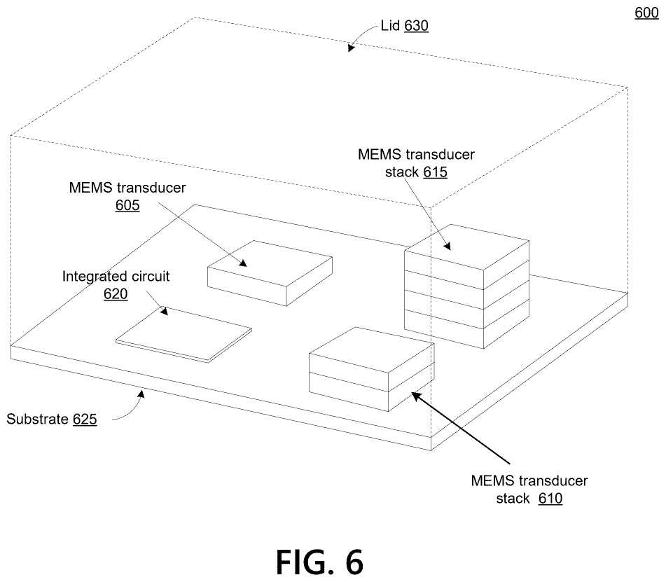

FIG. 6 shows an example transducer assembly 600 comprising multiple MEMS devices. The transducer assembly 600 may comprise a plurality of MEMS devices (e.g., MEMS transducer 605, MEMS transducer stack 610, and MEMS transducer stack 615). In an example, each MEMS device may be associated with a different maximum SPL rating, a different dynamic range, a different noise performance, etc.

The MEMS devices in the transducer assembly 600 may correspond to one or more MEMS transducers as described herein (e.g., as described with respect to FIG. 1A, 1B, 3, 4A, 4B, 4C, or 5). For example, the MEMS transducer 605 may be similar to the MEMS transducer 105 as described with respect to FIG. 1A. Alternatively, the MEMS transducer 605 may correspond to the MEMS transducer 305 as described with respect to FIG. 3 (e.g., with a cap for reduced back cavity compliance). The MEMS transducer stack 610 and the MEMS transducer stack 615 may correspond to the MEMS transducer stack 405 as described with respect to FIG. 4. In an example, the MEMS transducer stack 610 and the MEMS transducer stack 615 may comprise a different number of MEMS transducers in their respective stacks. For example, as shown in FIG. 6, the MEMS transducer stack 610 may comprise two MEMS transducers, while the MEMS transducer stack 615 may comprise four MEMS transducers. In an example, the MEMS transducer 605 may be associated with first maximum SPL rating, the MEMS transducer stack 610 may be associated with a second maximum SPL rating that is higher than the first maximum SPL rating, and the MEMS transducer stack 615 may be associated with a third maximum SPL rating that is higher than the second maximum SPL rating.

The MEMS assembly 600 may additionally comprise an integrated circuit 620 (e.g., an ASIC) which may be used to process signal output from the different MEMS devices. The integrated circuit 620 may provide a gain ranging function by switching between different MEMS devices. The integrated circuit 620 may select a MEMS device from which signal is to be processed based on an SPL range of an audio to be measured. For example, the integrated circuit 620 may use signal output from the MEMS transducer 605 if the received audio level is lower than the first maximum SPL rating. The integrated circuit 620 may use signal output from the MEMS transducer 610 if the received audio level is higher than the first maximum SPL rating but lower than the second maximum SPL rating. The integrated circuit 620 may use signal output from the MEMS transducer 615 if the received audio level is higher than the second maximum SPL rating.

Additionally, or alternatively, the integrated circuit 620 may select a MEMS device from which signal is to be processed based on a desired SNR. For example, the integrated circuit may select the MEMS transducer 605 to achieve a higher SNR since the MEMS transducer stacks may have poorer noise performance (e.g., because of lower source capacitance). Conversely, the integrated circuit may select a MEMS transducer stack (e.g., the MEMS transducer stack 610 or the MEMS transducer stack 615) to achieve a higher dynamic range if SNR is not a concern.

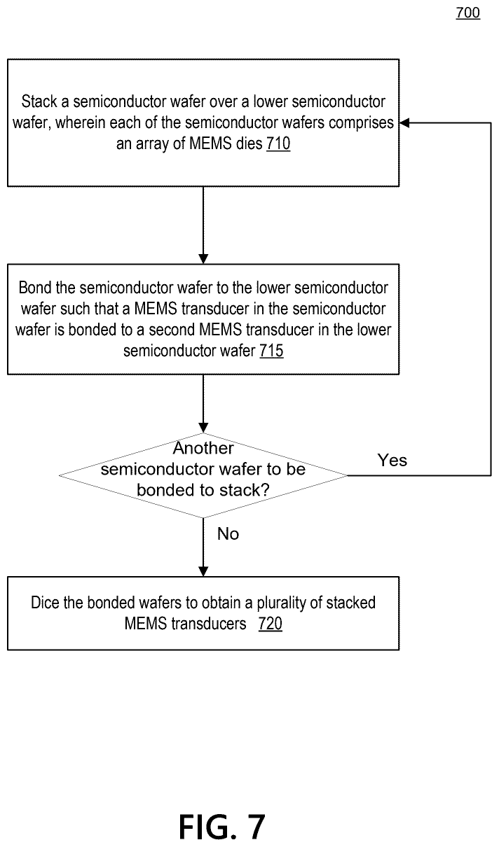

FIG. 7 shows an example method 700 for assembling a MEMS transducer stack. The example method 700 may be used to fabricate the MEMS transducer stack 405 as described with respect to FIGS. 4A-4C.

At step 710, a semiconductor wafer may be stacked over a lower semiconductor wafer. Each of the semiconductor wafers may correspond to processed silicon wafers and may comprise an array of MEMS dies. Each MEMS die may correspond to a capacitive MEMS transducer comprising a diaphragm and a backplate (e.g., similar to the MEMS transducer 105 as described with respect to FIG. 1A). Stacking the wafers may comprise aligning the wafers such that a diaphragm (or a backplate) of a MEMS transducer from the lower semiconductor wafer is aligned with a backplate (or a diaphragm) of a MEMS transducer from the semiconductor wafer that is stacked over the lower semiconductor wafer. Stacking the semiconductor wafers may comprise introducing another wafer in between to provide an interposer die (e.g., as described with respect to FIG. 4B) that may provide one or more interposer(s) for routing connections between MEMS transducers from the lower semiconductor wafer and the MEMS transducers from the semiconductor wafer that is stacked over the lower semiconductor wafer.

At step 715, the semiconductor wafer may be bonded to the lower semiconductor wafer using a wafer bonding technique (e.g., direct bonding, adhesive bonding, surface activated bonding, plasma activated bonding, anodic bonding, eutectic bonding, or any other wafer bonding technique). Bonding the semiconductor wafers may result in a MEMS transducer from the semiconductor wafer being bonded to a MEMS transducer from the lower semiconductor wafer. Bonding the semiconductor wafers may comprise using an intermediate layer between the semiconductor wafers (e.g., if using adhesive bonding or eutectic bonding), in which case the intermediate layer may be applied when stacking the semiconductor wafers (e.g., at step 710). Steps 710 and 715 may be repeated if one or more additional semiconductor wafers (e.g., comprising additional MEMS dies) are to be stacked and bonded to the lower semiconductor wafers.

At step 720, and if no additional semiconductor wafers are to be stacked, the bonded wafers may be diced (e.g., using mechanical sawing or laser cutting) to obtain a plurality of MEMS transducer stacks. The number of MEMS transducers in each MEMS transducer stack may be equal to the number of wafers that were bonded using steps 710 and 715.

A microelectromechanical systems (MEMS) transducer may comprise: a backplate; a diaphragm separated from the backplate by a width; and a cap affixed over the diaphragm. The cap may enclose a cavity and may comprise an opening that has substantially the same dimensions as a boundary of the diaphragm. The diaphragm may be circular and the opening of the cavity may be circular with a diameter that is equal to a diameter of the diaphragm. A capacitor may comprise the diaphragm and the backplate. The diaphragm may be configured to deform in response to an incident sound pressure wave. The deformation of the diaphragm may cause a change in capacitance of the capacitor. The MEMS transducer may comprise an integrated circuit configured to generate an output signal based on a change in the capacitance of the capacitor. The cap may comprise/may be fabricated from silicon, a ceramic, or a metal. The diaphragm and/or the backplate may comprise/may be fabricated from at least one of single-crystal silicon or polysilicon. The MEMS transducer may be stacked over and attached to a second MEMS transducer comprising a second backplate and a second diaphragm.

A sound pressure measurement device may comprise a MEMS transducer, a substrate, and a lid. The MEMS transducer may comprise: a backplate, a diaphragm separated from the backplate by a width, and a cap affixed over the diaphragm. The cap may enclose a cavity and may comprise an opening that has substantially the same dimensions as a boundary of the diaphragm. The MEMS transducer may be mounted on an inlet in the substrate such that the backplate is above the inlet. The lid may be attached to the substrate and may encapsulate the MEMS transducer. A capacitor may comprise the diaphragm and the backplate. The sound pressure measurement device may further comprise an integrated circuit configured to generate an output signal based on a change in capacitance of the capacitor. The diaphragm may be configured to deform in response to an incident sound pressure wave, and the deformation of the diaphragm may cause a change in capacitance of the capacitor. The diaphragm may be circular and the opening of the cavity may be circular with a diameter that is equal to a diameter of the diaphragm. The cap may comprise/may be fabricated from silicon, a ceramic, or a metal. The diaphragm and/or the backplate may comprise/may be fabricated from at least one of single-crystal silicon or polysilicon.

A microelectromechanical systems (MEMS) device may comprise a plurality of stacked MEMS transducers. The plurality of stacked MEMS transducers may comprise at least a first MEMS transducer and a second MEMS transducer. The first MEMS transducer may comprise a first backplate and a first diaphragm over the first backplate, and the second MEMS transducer may comprise a second backplate and a second diaphragm over the second backplate. The second MEMS transducer may be stacked over and attached to the first MEMS transducer such that the second backplate is above the first diaphragm. The first backplate and the first diaphragm may correspond to a first capacitor and the second backplate and the second diaphragm may correspond to a second capacitor. The first capacitor and the second capacitor may be wired in series to a voltage source. The voltage source may provide a biasing voltage to the first MEMS transducer and the second MEMS transducer. The MEMS device may comprise an integrated circuit configured to generate an output signal based on a change in a first capacitance of the first capacitor and a change in a second capacitance of the second capacitor. A biasing voltage may be applied to only one MEMS transducer of the plurality of MEMS transducers. An integrated circuit may be configured to generate an output signal based on a change in capacitance of the one MEMS transducer of the plurality of stacked MEMS transducers. The MEMS device may further comprise a substrate. The substrate may comprise an inlet. The first MEMS transducer may be mounted on the inlet such that the first backplate is above the inlet. The MEMS device may comprise a lid attached to the substrate and encapsulating the plurality of stacked MEMS transducers. The first MEMS transducer may be identical to the second MEMS transducer. The first diaphragm, the first backplate, the second diaphragm, or the second backplate may comprise/may be fabricated from at least one of single-crystal silicon or polysilicon.

One or more aspects of the disclosure may be embodied in computer-usable data or computer-executable instructions, such as in one or more program modules, executed by one or more computers or other devices to perform the operations described herein. Generally, program modules include routines, programs, objects, components, data structures, and the like that perform particular tasks or implement particular abstract data types when executed by one or more processors in a computer or other data processing device. The computer-executable instructions may be stored as computer-readable instructions on a computer-readable medium such as a hard disk, optical disk, removable storage media, solid-state memory, RAM, and the like. The functionality of the program modules may be combined or distributed as desired in various embodiments. In addition, the functionality may be embodied in whole or in part in firmware or hardware equivalents, such as integrated circuits, application-specific integrated circuits (ASICs), field programmable gate arrays (FPGA), and the like. Particular data structures may be used to more effectively implement one or more aspects of the disclosure, and such data structures are contemplated to be within the scope of computer executable instructions and computer-usable data described herein.

Various aspects described herein may be embodied as a method, an apparatus, or as one or more computer-readable media storing computer-executable instructions. Accordingly, those aspects may take the form of an entirely hardware embodiment, an entirely software embodiment, an entirely firmware embodiment, or an embodiment combining software, hardware, and firmware aspects in any combination. In addition, various signals representing data or events as described herein may be transferred between a source and a destination in the form of light or electromagnetic waves traveling through signal-conducting media such as metal wires, optical fibers, or wireless transmission media (e.g., air or space). In general, the one or more computer-readable media may be and/or include one or more non-transitory computer-readable media.

Aspects of the disclosure have been described in terms of illustrative embodiments thereof. Numerous other embodiments, modifications, and variations within the scope and spirit of the appended claims will occur to persons of ordinary skill in the art from a review of this disclosure. For example, one or more of the steps depicted in the illustrative figures may be performed in other than the recited order, and one or more depicted steps may be optional in accordance with aspects of the disclosure.

1. A microelectromechanical systems (MEMS) transducer comprising:
a backplate;
a diaphragm separated from the backplate by a width; and
a cap affixed over the diaphragm,
wherein the cap encloses a cavity and comprises an opening that has substantially the same dimensions as a boundary of the diaphragm.

2. The MEMS transducer of claim 1, wherein the diaphragm is circular and the opening of the cavity is circular with a diameter that is equal to a diameter of the diaphragm.

3. The MEMS transducer of claim 1, wherein:
a capacitor comprises the diaphragm and the backplate,
the diaphragm is configured to deform in response to an incident sound pressure wave, and
the deformation of the diaphragm is configured to cause a change in capacitance of the capacitor.

4. The MEMS transducer of claim 1, further comprising an integrated circuit configured to generate an output signal based on a change in the capacitance of the capacitor.

5. The MEMS transducer of claim 1, wherein the cap comprises at least one of silicon, a ceramic, or a metal.

6. The MEMS transducer of claim 1, wherein the diaphragm or the backplate comprises at least one of single-crystal silicon or polysilicon.

7. The MEMS transducer of claim 1, wherein the MEMS transducer is stacked over and attached to a second MEMS transducer comprising a second backplate and a second diaphragm.

8. A sound pressure measurement device comprising:
a MEMS transducer;
a substrate; and
a lid,
wherein the MEMS transducer comprises:
a backplate;
a diaphragm separated from the backplate by a width; and
a cap affixed over the diaphragm, wherein the cap encloses a cavity and comprises an opening that has substantially the same dimensions as a boundary of the diaphragm, and wherein the MEMS transducer is mounted on an inlet in the substrate such that the backplate is above the inlet, and wherein the lid is attached to the substrate and encapsulates the MEMS transducer.

9. The sound pressure measurement device of claim 8, wherein a capacitor comprises the diaphragm and the backplate, and wherein the sound pressure measurement device further comprises an integrated circuit configured to generate an output signal based on a change in capacitance of the capacitor.

10. The sound pressure measurement device of claim 8, wherein the diaphragm is circular and the opening of the cavity is circular with a diameter that is equal to a diameter of the diaphragm.

11. The sound pressure measurement device of claim 8, wherein: a capacitor comprises the diaphragm and the backplate, the diaphragm is configured to deform in response to an incident sound pressure wave, and the deformation of the diaphragm causes a change in capacitance of the capacitor.

12. The sound pressure measurement device of claim 8, wherein: the cap comprises silicon, a ceramic, or a metal, and the diaphragm or the backplate comprises at least one of single-crystal silicon or polysilicon.

13. A microelectromechanical systems (MEMS) device comprising a plurality of stacked MEMS transducers, wherein:
the plurality of stacked MEMS transducers comprises at least a first MEMS transducer and a second MEMS transducer;
the first MEMS transducer comprises a first backplate and a first diaphragm over the first backplate;
the second MEMS transducer comprises a second backplate and a second diaphragm over the second backplate; and
the second MEMS transducer is stacked over and attached to the first MEMS transducer such that the second backplate is above the first diaphragm.

14. The MEMS device of claim 13, wherein:
the first backplate and the first diaphragm correspond to a first capacitor;
the second backplate and the second diaphragm correspond to a second capacitor,
the first capacitor and the second capacitor are wired in series to a voltage source, and
the voltage source provides a biasing voltage to the first MEMS transducer and the second MEMS transducer.

15. The MEMS device of claim 13, further comprising an integrated circuit configured to generate an output signal based on a change in a first capacitance of the first capacitor and a change in a second capacitance of the second capacitor.

16. The MEMS device of claim 13, wherein a biasing voltage is applied to only one MEMS transducer of the plurality of MEMS transducers.

17. The MEMS device of claim 16, further comprising an integrated circuit configured to generate an output signal based on a change in capacitance of the one MEMS transducer of the plurality of stacked MEMS transducers.

18. The MEMS device of claim 13, further comprising a substrate comprising an inlet, wherein the first MEMS transducer is mounted on the inlet such that the first backplate is above the inlet.

19. The MEMS device of claim 18, further comprising a lid attached to the substrate and encapsulating the plurality of stacked MEMS transducers.

20. The MEMS device of claim 13, wherein the first MEMS transducer is identical to the second MEMS transducer.
